(19) United States
(12) Patent Application Publication
(10) Pub. No.: US 2026/0322375 A1
(43) Pub. Date: Oct. 15, 2026

(54) CONTROL CIRCUIT FOR SEMICONDUCTOR DEVICE AND SEMICONDUCTOR SYSTEM

(71) Applicants: KABUSHIKI KAISHA TOSHIBA, Kawasaki-shi (JP); TOSHIBA ELECTRONIC DEVICES & STORAGE CORPORATION, Kawasaki-shi (JP)

(72) Inventors: Takato YAMAMOTO, Kawasaki Kanagawa (JP); Yusuke KOBAYASHI, Yokohama Kanagawa (JP); Tomoko MATSUDAI, Shibuya Tokyo (JP); Tatsunori SAKANO, Shinagawa Tokyo (JP); Ryohei GEJO, Kawasaki Kanagawa (JP); Kota KATO, Kawasaki Kanagawa (JP)

(73) Assignees: KABUSHIKI KAISHA TOSHIBA, Kawasaki-shi (JP); TOSHIBA ELECTRONIC DEVICES & STORAGE CORPORATION, Kawasaki-shi (JP)

(21) Appl. No.: 19/463,324

(22) Filed: Jan. 29, 2026

(30) Foreign Application Priority Data
Mar. 14, 2025 (JP) 2025-041034

(51) Int. Cl. H03K 17/16

(52) U.S. Cl. CPC H03K 17/168; H03K 2217/0036

(57) ABSTRACT

According to one embodiment, a control circuit for a semiconductor device includes a controller configured to control a semiconductor device. The semiconductor device includes first and electrodes, a semiconductor member, first and second control electrodes. The controller performs a second control-on operation multiple times in a first control-on period, to change a second control potential of the second control electrode from a first potential to a second potential. In a first condition, the first potential is less than a second threshold voltage at the second control electrode and the second potential is equal to or greater than the second threshold voltage. In a second condition, in the first control-on period, the first control potential of the first control electrode is equal to or less than the first threshold voltage.

### CROSS-REFERENCE TO RELATED APPLICATIONS

This application is based upon and claims the benefit of priority from Japanese Patent Application No. 2025-041034, filed on Mar. 14, 2025; the entire contents of which are incorporated herein by reference.

### FIELD

Embodiments described herein relate generally to a control circuit for a semiconductor device and a semiconductor system.

### BACKGROUND

For example, a semiconductor device is controlled by a control circuit. It is desirable to reduce losses in the semiconductor device.

### BRIEF DESCRIPTION OF THE DRAWINGS

FIG. 1 is a schematic diagram illustrating an operation of a control circuit for a semiconductor device according to a first embodiment;

FIG. 2 is a schematic view illustrating the control circuit for the semiconductor device according to the first embodiment;

FIG. 3 is a schematic diagram illustrating the operation of the control circuit for the semiconductor device according to the first embodiment;

FIG. 4 is a schematic diagram illustrating the operation of the control circuit for the semiconductor device according to the first embodiment;

FIG. 5 is a schematic diagram illustrating the operation of the control circuit for the semiconductor device according to the first embodiment;

FIG. 6 is a schematic diagram illustrating the operation of the control circuit for the semiconductor device according to the first embodiment;

FIG. 7 is a schematic diagram illustrating the operation of the control circuit for the semiconductor device according to the first embodiment;

FIG. 8 is a schematic diagram illustrating the operation of the control circuit for the semiconductor device according to the first embodiment;

FIG. 9 is a schematic cross-sectional view illustrating a semiconductor device to which the control circuit according to the first embodiment is applied;

FIG. 10 is a schematic cross-sectional view illustrating a semiconductor device to which the control circuit according to the first embodiment is applied;

FIG. 11 is a schematic cross-sectional view illustrating a semiconductor device to which the control circuit according to the first embodiment is applied;

FIG. 12 is a schematic cross-sectional view illustrating a semiconductor device to which the control circuit according to the first embodiment is applied;

FIG. 13 is a schematic cross-sectional view illustrating a semiconductor device to which the control circuit according to the first embodiment is applied;

FIG. 14 is a schematic cross-sectional view illustrating a semiconductor device to which the control circuit according to the first embodiment is applied; and

FIG. 15 is a schematic cross-sectional view illustrating a semiconductor device to which the control circuit according to the first embodiment is applied.

### DETAILED DESCRIPTION

According to one embodiment, a control circuit for a semiconductor device includes a controller configured to control a semiconductor device. The semiconductor device includes a first electrode, a second electrode, a semiconductor member provided between the first electrode and the second electrode, a first control electrode, and a second control electrode. At least a part of the semiconductor member is between the first electrode and the first control electrode. At least a part of the semiconductor member is between the second control electrode and the second electrode. The controller is configured to perform a second control-on operation multiple times in a first control-on period, to change a second control potential of the second control electrode from a first potential to a second potential. A first condition or a second condition is satisfied. In the first condition, in the first control-on period, a first control potential of the first control electrode is equal to or greater than a first threshold voltage. In the first condition, the first potential is less than a second threshold voltage at the second control electrode and the second potential is equal to or greater than the second threshold voltage. In the second condition, in the first control-on period, the first control potential of the first control electrode is equal to or less than the first threshold voltage. In the second condition, the first potential is equal to or greater than the second threshold voltage at the second control electrode and the second potential is less than the second threshold voltage.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

### First Embodiment

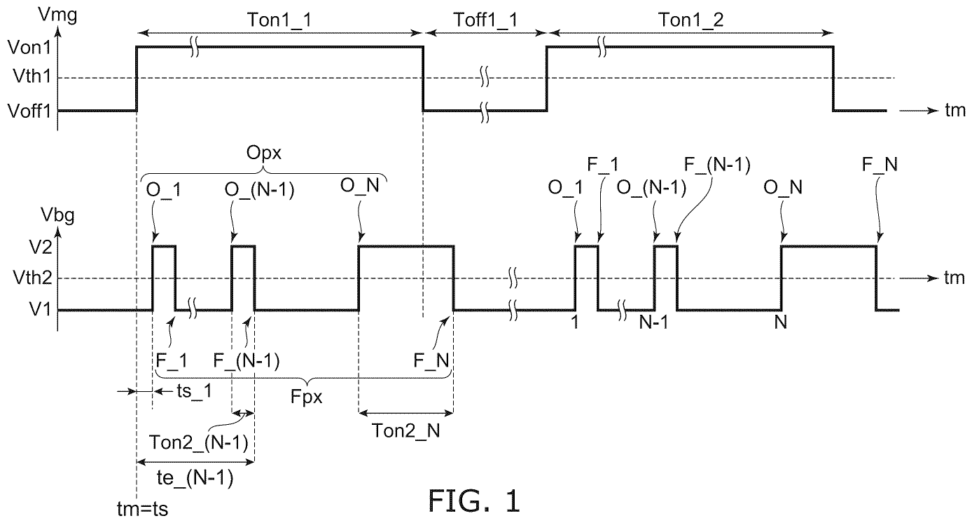

FIG. 1 is a schematic diagram illustrating an operation of a control circuit for a semiconductor device according to a first embodiment.

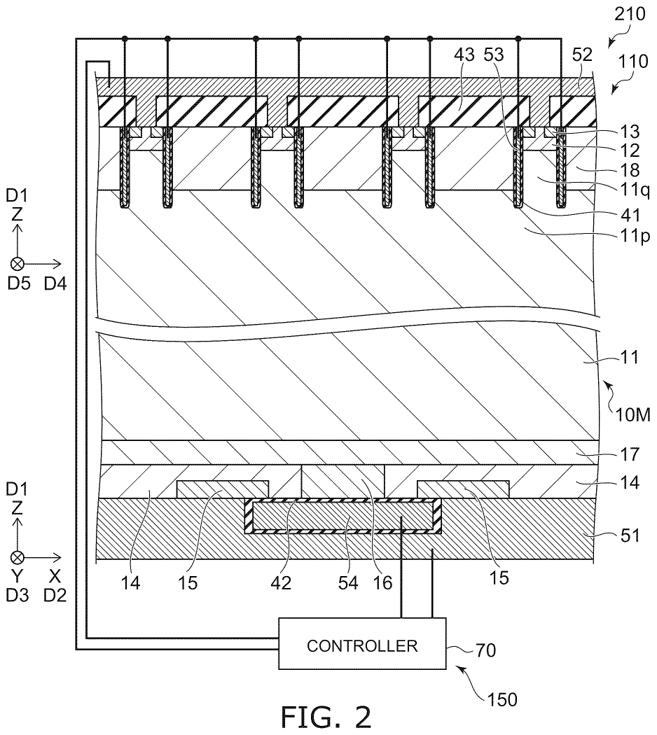

FIG. 2 is a schematic view illustrating the control circuit for the semiconductor device according to the first embodiment.

As shown in FIG. 2, a control circuit 150 according to the embodiment includes a controller 70. The controller 70 is configured to control a semiconductor device 110. A semiconductor system 210 according to the embodiment includes the semiconductor device 110 and the control circuit 150.

The semiconductor device 110 includes a first electrode 51, a second electrode 52, a first control electrode 53, a second control electrode 54, and a semiconductor member 10M. The semiconductor member 10M is provided between the first electrode 51 and the second electrode 52. At least a part of the semiconductor member 10M is between the first electrode 51 and the first control electrode 53. At least a part of the semiconductor member 10M is between the second control electrode 54 and the second electrode 52.

The semiconductor member 10M includes, for example, an upper face and a lower face. For example, the first electrode 51 is provided on the lower face. The second electrode 52 is provided on the upper face. The first control electrode 53 is provided on the upper face side, for example. The second control electrode 54 is provided on the lower face side.

The semiconductor member 10M includes a first semiconductor region 11 of a first conductivity type, a second semiconductor region 12 of a second conductivity type, a third semiconductor region 13 of the first conductivity type, a fourth semiconductor region 14 of the second conductivity type, and a fifth semiconductor region 15 of the first conductivity type.

The semiconductor device 110 may be an n-channel type or a p-channel type. The control circuit 150 according to the embodiment may satisfy the first condition or the second condition. In the first condition, the semiconductor device 110 is an n-channel type. In the second condition, the semiconductor device 110 is a p-channel type. In the first condition, the first conductivity type is n-type and the second conductivity type is p-type. In the second condition, the first conductivity type is p-type and the second conductivity type is n-type.

The second semiconductor region 12 is provided between the first semiconductor region 11 and the second electrode 52. The second semiconductor region 12 may be in contact with the first semiconductor region 11. The third semiconductor region 13 is provided between at least a part of the second semiconductor region 12 and the second electrode 52. The third semiconductor region 13 may be in contact with the second semiconductor region 12 and the second electrode 52. The third semiconductor region 13 is electrically connected to the second electrode 52. The first semiconductor region 11 is, for example, a drift layer.

The fourth semiconductor region 14 is provided between the first electrode 51 and the first semiconductor region 11. The first semiconductor region 11 is located between the second semiconductor region 12 and the fourth semiconductor region 14. The fifth semiconductor region 15 is provided between the first electrode 51 and at least a part of the fourth semiconductor region 14. The fifth semiconductor region 15 does not contact the first semiconductor region 11. The fifth semiconductor region 15 is electrically connected to the first electrode 51.

The semiconductor device 110 includes a first insulating member 41 and a second insulating member 42. At least a part of the first insulating member 41 is provided between the first control electrode 53 and the first semiconductor region 11, between the first control electrode 53 and the second semiconductor region 12, and between the first control electrode 53 and the third semiconductor region 13. The first insulating member 41 contacts the first control electrode 53, the first semiconductor region 11, the second semiconductor region 12, and the third semiconductor region 13. The first insulating member 41 electrically insulates the first control electrode 53 and the semiconductor member 10M from each other.

At least a part of the second insulating member 42 is provided between the second control electrode 54 and the first semiconductor region 11, between the second control electrode 54 and the fourth semiconductor region 14, and between the second control electrode 54 and the fifth semiconductor region 15. The second insulating member 42 electrically insulates the second control electrode 54 and the semiconductor member 10M from each other.

The semiconductor device 110 is, for example, an IGBT (Insulated Gate Bipolar Transistor) that includes two types of control electrodes. The potential of the first control electrode 53 and the potential of the second control electrode 54 are controlled by the controller 70 of the control circuit 150.

When the semiconductor device 110 performs IGBT operation and the first control electrode 53 functions as a main gate electrode that switches the IGBT, for example, the first electrode 51 functions as a collector electrode, the second electrode 52 functions as an emitter electrode, and the second control electrode 54 functions as a sub-gate electrode that controls the current path of the IGBT.

FIG. 1 illustrates an example of the potential of the first control electrode 53 (first control potential Vmg) and the potential of the second control electrode 54 (second control potential Vbg). The horizontal axis of FIG. 1 is time tm.

The controller 70 switches the first control potential Vmg of the first control electrode 53 between a first control-off potential Voff1 and a first control-on potential Von1.

FIG. 1 illustrates a case of the first condition (n-channel type). In the first condition, the first control-off potential Voff1 is less than a first threshold voltage Vth1. In the first condition, the first control-on potential Von1 is equal to or greater than the first threshold voltage Vth1. The period in which the first control potential Vmg is the first control-on potential Von1 corresponds to the first control-on period Ton1_1.

In the embodiment, a first control-off period Toff1_1 may be provided between a plurality of first control-on periods (such as a first-time first control-on period Ton1_1 and a second-time first control-on period Ton1_2, etc.). The first control-on period Ton1_1 and the first control-off period Toff1_1 may be repeated. A length of the first-time first control-on period Ton1_1 may be different from a length of the second-time first control-on period Ton1_2.

As shown in FIG. 1, the controller 70 switches the second control potential Vbg of the second control electrode 54 between a first potential V1 and a second potential V2. In the first condition (n-channel type), the first potential V1 is less than a second threshold voltage Vth2 at the second control electrode 54. The second potential V2 is equal to or greater than the second threshold voltage Vth2. The controller 70 is configured to perform a second control-on operation Opx multiple times in the first control-on period Ton1 in which the first control potential Vmg of the first control electrode 53 is equal to or greater than the first threshold voltage Vth1. In the second control-on operation Opx, the controller 70 changes the second control potential Vbg of the second control electrode 54 from the first potential V1 to the second potential V2.

On the other hand, in the second condition (p-channel type), the first control-off potential Voff1 exceeds the first threshold voltage Vth1, and the first control-on potential Von1 is equal to or lower than the first threshold voltage Vth1. The period in which the first control potential Vmg is equal to the first control-on potential Von1 corresponds to the first control-on period Ton1_1. In the second condition, the first potential V1 is equal to or higher than the second threshold voltage Vth2 at the second control electrode 54. The second potential V2 is lower than the second threshold voltage Vth2. The controller 70 is configured to perform the second control-on operation Opx multiple times in the first control-on period Ton1_1 in which the first control potential Vmg of the first control electrode 53 is equal to or lower than the first threshold voltage Vth1. In the second control-on operation Opx, the controller 70 changes the second control potential Vbg of the second control electrode 54 from the first potential V1 to the second potential V2.

The first condition illustrated in FIG. 1 will be further explained below. The following explanation can be applied to the second condition by reversing the height relationship of the potentials.

For example, in the second control-on operation Opx, the controller 70 applies a pulse voltage to the second control electrode 54. In the first control-on period Ton1_1, multiple pulse voltages are applied. The rise (ON) of each of the multiple pulses occurs in the first control-on period Ton1_1.

Such a pulse voltage can realize a conduction not through a pn junction, due to highly injected electrons, for example, immediately after the second control gate is turned-on. For example, the on-voltage in the second control gate on-period is lower than the on-voltage in the second control gate off-period. This can reduce the time average of conduction loss, for example, when the second control gate is repeatedly turned-on and off. According to the embodiment, a control circuit for a semiconductor device capable of reducing losses can be provided.

For example, when the first control electrode 53 is in the on state and the second control electrode 54 is in the off state, many carriers are accumulated in the drift layer. Bipolar conduction occurs through the pn junction.

On the other hand, for example, when the first control electrode 53 is in the on state and the second control electrode 54 switches from the off state to the on state, the carriers in the drift layer decrease. Then, electron-based conduction occurs without passing through the pn junction.

While the first control electrode 53 is in the on state, the second control electrode 54 repeatedly turns on and off, switching the above states multiple times. Switching of conduction without passing through the pn junction occurs steadily. The time average of the on-voltage decreases. Conduction losses are reduced.

For example, when the first control electrode 53 is turned-on, the following state is considered to occur. For example, when the first control electrode 53 is turned-on, the IGBT is turned-on. In the period from turning on to the first time, bipolar conduction occurs due to carriers accumulated at a high density. Due to conduction through the pn junction, the on-voltage includes a built-in voltage. At the first time, the second control electrode 54 is turned-on, and an n-channel is formed on the first electrode 51 side. Electrons can move from the second electrode 52 to the first electrode 51 through only the n-type semiconductor. In such conduction that does not go through the pn junction, the on-voltage does not include a built-in voltage. In the period from the first time to the second time, the bipolar conduction transitions to electronic conduction, and the on-voltage gradually decreases. In the period from the second time to the third time, the carriers in the drift layer gradually decrease (from the first electrode 51 side), but the high injection state continues. Due to electronic conduction that reduces the built-in voltage, the on-voltage of the second control electrode 54 is reduced. In a period after the third time, a part of the drift layer is low-injected, and the drift layer has a high resistance depending on the size of the low-injection region. The time from turning on to the first time is, for example, 1000 ns. The time from turning on to the second time is, for example, 1015 ns. The time from turning on to the third time is, for example, 1120 ns.

In the above example, for example, in the period from the second time to the third time, the second control electrode 54 is turned-off to return to bipolar conduction. This suppresses the decrease in carriers and makes it possible to accumulate carriers at a high density in the drift layer again. This makes it possible to suppress the drift layer from becoming highly resistant after the third time.

As shown in FIG. 1, the second control-on operation Opx is configured to be performed multiple times. In the second control-on operation Opx, the controller 70 changes the second control potential Vbg of the second control electrode 54 from the first potential V1 to the second potential V2.

As shown in FIG. 1, a second control-off operation Fpx is performed after each of the plurality of second control-on operations Opx. In the second control-off operation Fpx, the controller 70 changes the second control potential Vbg from the second potential V2 to the first potential V1.

The controller 70 performs N times of the second control-on operations Opx being above-mentioned. “N” is an integer equal to or greater than 2. The first to Nth second control-on operations Opx are performed in the first control-on period Ton1. The first to (N−1)th “second control-off operations Fpx” are performed in the first control-on period Ton1. The Nth “second control-off operation Fpx” may be performed after the first control-on period Ton1.

As shown in FIG. 1, the Nth “second control-on operation Opx2 includes a first ”second control-on operation O_1″, an (N−1)th “second control-on operation O_(N−1)”, and an Nth “second control-on operation O_N”. The Nth “second control-off operation Fpx” includes a first “second control-off operation F_1”, an (N−1)th “second control-off operation F_(N−1)”, and an Nth “second control-off operation F_N”.

The (N−1)th “second control-off operation F_(N−1)” is performed between the (N−1)th “second control-on operation O_(N−1)” and the Nth “second control-on operation O_N”.

In this way, after the (N−1)th “second control-on operation O_(N−1)” and before the Nth “second control-on operation O_N”, the controller 70 is configured to perform the (N−1)th “second control-off operation F_(N−1)” in which the second control potential Vbg is changed from the second potential V2 to the first potential V1. In the (N−1)th “second control-off operation F_(N−1)”, the controller 70 changes the second control potential Vbg from the second potential V2 to the first potential V1.

The time te_(N−1) between a reference time ts at which the first control potential Vmg exceeds the first threshold voltage Vth1 and the time of the (N−1)th “second control-off operation F_(N−1)” may be 0.99 times or less the length of the first control-on period Ton1_1.

The time ts_1 between the reference time ts at which the first control potential Vmg exceeds the first threshold voltage Vth1 and the start time of the first second control-on operation O_1 may be 0.01 times or more the length of the first control-on period Ton1_1.

The time Ton2_(N−1) between the time of the (N−1)th “second control-on operation O_(N−1)” and the time of the (N−1)th “second control-off operation F_(N−1)” may be shorter than the time Ton2_N between the time of the Nth second control-on operation O_N and the time of the Nth “second control-off operation F_N”. The time of the Nth “second control-off operation F_N” may be after the end of the first control-on period Ton1.

In a case where the time of the Nth “second control-off operation F_N ”is later than the first control-on period Ton1, the time between the time of the Nth “second control-off operation F_N” and the end time of the first control-on period Ton1 may be, for example, more than 0 μs and less than or equal to 200 μs. In a case where the time of the Nth “second control-off operation F_N” is earlier than the first control-on period Ton1, the time between the time of the Nth “second control-off operation F_N” and the start time of the first control-on period Ton1 may be, for example, more than 0 μs and less than or equal to 100 μs.

In the embodiment, the first, second, and Nth “first control-on periods” are denoted as “Ton1_1”, “Ton1_2”, and “Ton1_N”, respectively. The lengths of these first control-on period may be constant or may differ from each other. The first, second, and Nth “first control-off periods” are denoted as “Toff1_1”, “Toff1_2”, and “Toff1_N”, respectively. The lengths of these “first control-off periods” may be constant or may differ from each other. In the “first control-off period”, the second control electrode 54 may be in an off state for a period that is, for example, 80% or more of the length of the “first control-off period”.

As described above, in the second condition, the first conductivity type is p-type and the second conductivity type is n-type. In this case, the height relationship between the first control-on potential Von1 and the first control-off potential Voff1 is the opposite of the height relationship in the first condition being mentioned above. In the case of the second condition, the height relationship between the first potential V1 and the second potential V2 is the opposite of the height relationship in the first condition being mentioned above.

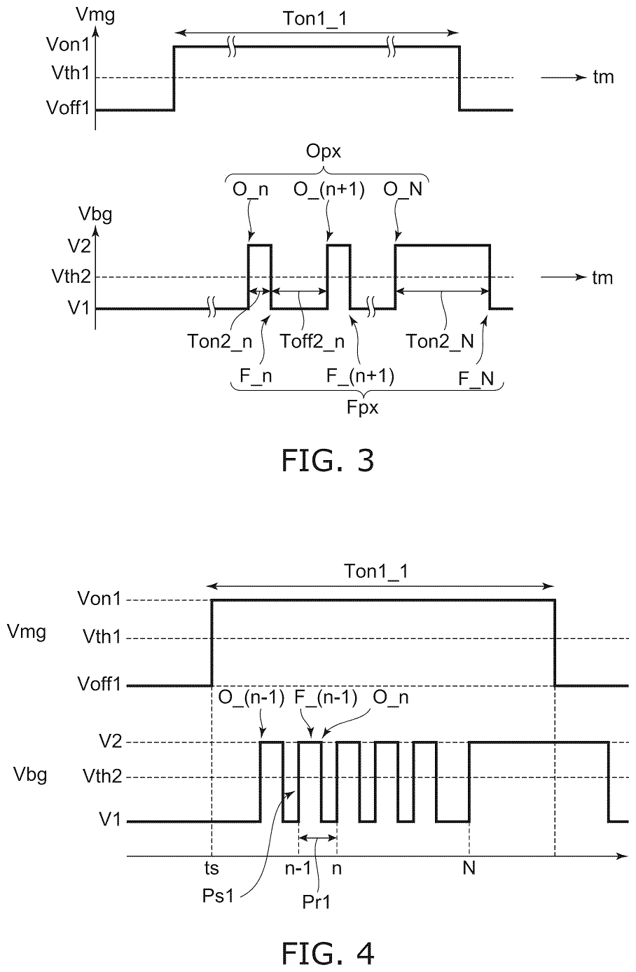

FIG. 3 is a schematic diagram illustrating the operation of the control circuit for the semiconductor device according to the first embodiment.

As shown in FIG. 3, the controller 70 is configured to perform an nth “second control-on operation Opx” and an nth “second control-off operation Fpx”. “n” is an integer not less than and not more than (N−1).

The nth “second control-off operation F_n” is performed after the nth “second control-on operation O_n” and before the (n+1)th “second control-on operation O_(n+1)”. In the nth “second control-off operation F_n”, the controller 70 changes the second control potential Vbg from the second potential V2 to the first potential V1.

The on-time Ton2_n between the time of the nth “second control-on operation O_n” and the time of the nth “second control-off operation F_n” may be not less than 5 ns and not more than 2 μs.

“n” may be an integer not less than 1 and not more than (N−2). The on-time Ton2_n between the time of the nth “second control-on-operation O_n” and the time of the nth “second control-off-operation F_n” corresponds to the on-time of the nth pulse. The off-time Toff2_n between the time of the nth “second control-off-operation F_n” and the time of the (n+1)th “second control-on-operation O_(n+1)” corresponds to the off-time after the nth pulse. For example, the on-time Ton2_n may be shorter than the off-time Toff2_n.

As already explained, the on-time Ton2_n may be not less than 5 ns and not more than 2μs. The off-time Toff2_n may be, for example, not less than 5 ns and not more than 3 μs. The off-time Toff2_n is, for example, shorter than the time between the time of the (N−1)th “second control-off operation F_(N−1)” and the time of the Nth “second control-on operation O_N”.

For example, the time Ton2_N between the time of the Nth “second control-on operation O_N” and the time of the Nth “second control-off operation F_N” may be longer than the ON time Ton2_n between the time of the nth “second control-on operation O_n” and the time of the nth “second control-off operation F_n”. The time Ton2_N may be, for example, not less than 5 μs and not more than 300 μs.

FIG. 4 is a schematic diagram illustrating the operation of the control circuit for the semiconductor device according to the first embodiment.

As shown in FIG. 4, the controller 70 is configured to perform a (n−1)th “second control-off operation F_(n−1)” after the (n−1)th “second control-on operation O_(n−1)” and before the nth “second control-on operation O_n”. “n” is an integer not less than 1 and not more than (N−1). In the (n−1)th “second control-off operation F_(n−1)”, the second control potential Vbg is changed from the second potential V2 to the first potential V1. The first to (n−1)th “second control-on operations O_(n−1)” include applying a pulse Ps1 to the second control electrode 54. In the first to (n-1)th “second control-on operations O_(n−1)”, the period Pr1 of the pulse Ps1 may be 5μs or less.

In the first to (n−1)th “second control-on operations O_(n−1)” (and second control-off operations F_(n−1)), the period Pr1 of the pulse Ps1 may be constant. The pulse Ps1 is applied continuously.

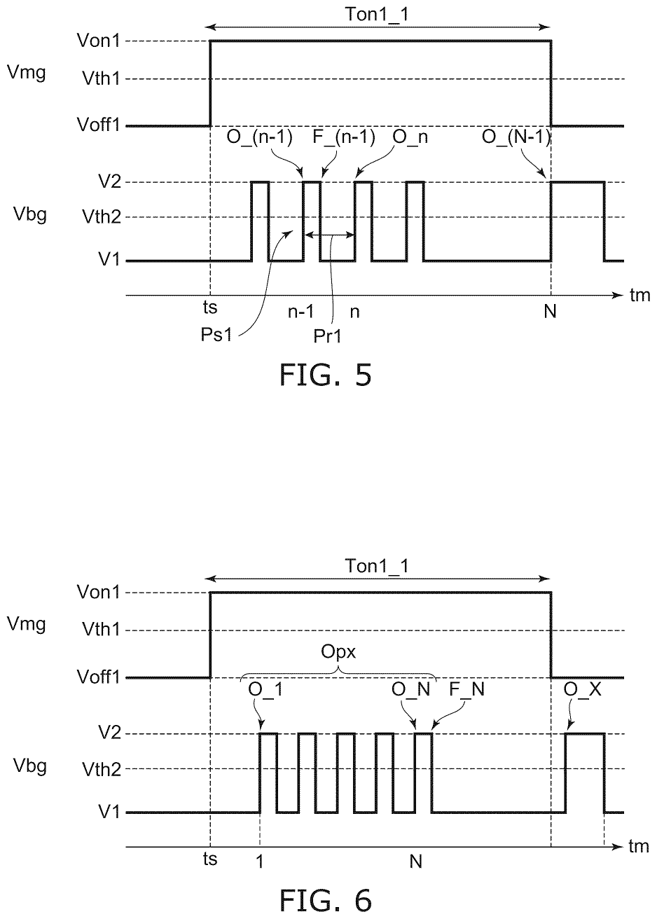

FIG. 5 is a schematic diagram illustrating the operation of the control circuit for the semiconductor device according to the first embodiment.

In FIG. 5 as well, the controller 70 is configured to perform the (n−1)th “second control-off operation F_(n−1)” after the (n−1)th “second control-on operation O_(n−1)” and before the nth “second control-on operation O_n”. The first through the (n−1)th “second control-on operations O_(n−1)” include application of the pulse Ps1 to the second control electrode 54. In the first through the (n−1)th “second control-on operations O_(n−1)”, the duty ratio of the pulse Ps1 may be 0.5 or less. For example, the on time Ton2_n illustrated in FIG. 3 may be less than or equal to the off time Toff2_n.

For example, in the first to (n−1)th “second control-on operations O_(n−1)” (and the second control-off operation F_(n−1), the period Pr1 of the pulse Ps1 may be constant. The pulse Ps1 is applied continuously.

As shown in FIG. 5, the time of the Nth “second control-on operation O_N” may overlap the end time of the first control-on period Ton1.

FIG. 6 is a schematic diagram illustrating the operation of the control circuit for the semiconductor device according to the first embodiment.

As shown in FIG. 6, the controller 70 performs the second control-on operation Opx N times in the first control-on period Ton1. For example, the first “second control-on operation O_1” to the Nth “second control-on operation O_N” are performed. The Nth “second control-off operation F_N” may be performed before the first control-on period Ton1. After the end of the first control-on period Ton1, another second control-on operation O_X may be performed.

FIG. 7 is a schematic diagram illustrating the operation of the control circuit for the semiconductor device according to the first embodiment.

As shown in FIG. 7, the controller 70 may set the second control potential Vbg to a plurality of different values equal to or greater than the second threshold voltage Vth2 in a plurality of second control-on operations Opx. For example, the second potential V2 in one of the plurality of performing the second control-on operation Opx is different from the second potential V2 in another one of the plurality of performing the second control-on operation Opx. In this example, in the first to (N−1) “second control-on operations O_(N−1)”, the second control potential Vbg is the second potential V2. In the Nth “second control-on operation O_N”, the second control potential Vbg is a potential (third potential V3) different from the second potential V2. The third potential V3 is equal to or greater than the second threshold voltage Vth2.

The first potential V1 in one of the plurality of performing the second control-on operation Opx may be different from the first potential V1 in another one of the plurality of performing the second control-on operation Opx.

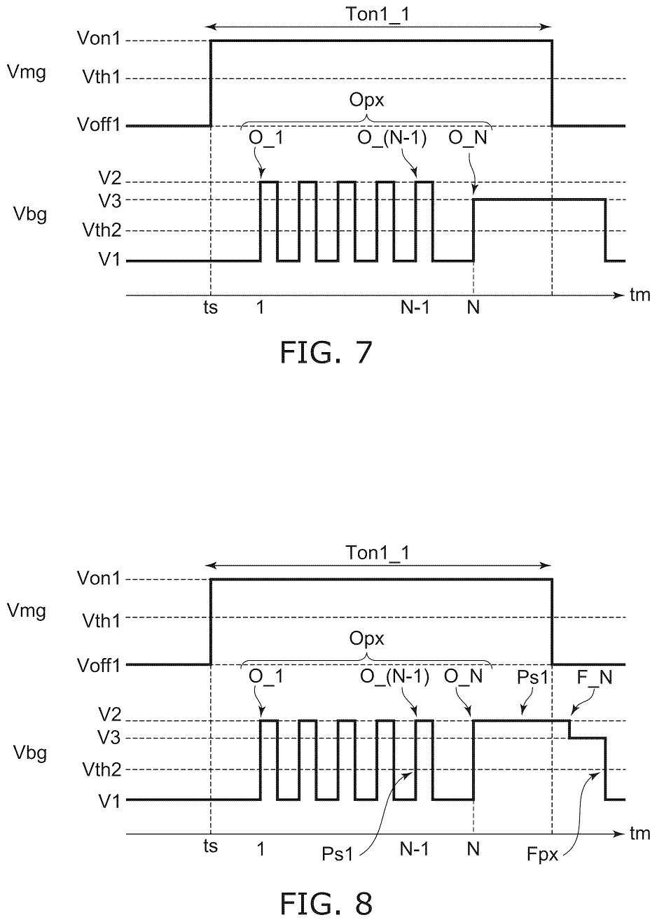

FIG. 8 is a schematic diagram illustrating the operation of the control circuit for the semiconductor device according to the first embodiment.

As shown in FIG. 8, the controller 70 may control the second control potential Vbg with the pulse Ps1 having three or more values in at least some of the plurality of second control-on operations Opx.

For example, the controller 70 performs the second control-on operation Opx N times. “N” is an integer equal to or greater than 2. In this example, in the first to (N−1)th “second control-on operations O_(N−1)”, the second control potential Vbg is controlled by a pulse Ps1 having two values.

The controller 70 is configured to perform an Nth “second control-off operation F_N” after an Nth “second control-on operation O_N”. In the Nth “second control-off operation F_N”, the second control potential Vbg changes from the second potential V2 to the first potential V1. In at least one of the Nth “second control-on operation O_N” and the Nth “second control-off operation F_N”, the second control potential Vbg is controlled by the pulse Ps1 having three or more values. In this example, the Nth second control-off operation F_N is performed by a potential having three values.

For example, the potential of the pulse Ps1 having three or more values changes from the first potential V1 to the second potential V2, and then changes from the second potential V2 to the third potential V3. The potential of the pulse Ps1 having three or more values becomes the first potential V1 after changing to the third potential V3. The third potential V3 is between the first potential V1 and the second potential V2. The third potential V3 is equal to or greater than the second threshold voltage Vth2.

In this example, before the end of the first control-on period Ton1, the second control potential Vbg is the second potential V2. After the end of the first control-on period Ton1, the second control potential Vbg becomes the third potential V3.

In the embodiment, the first control potential Vmg may be the potential of the first control electrode 53 with the potential of the second electrode 52 as a reference. The second control potential Vbg may be the potential of the second control electrode 54 with the potential of the first electrode 51 as a reference.

As in the example shown in FIG. 2, the semiconductor device 110 may further include a third insulating member 43. The third insulating member 43 is between the first control electrode 53 and the second electrode 52. The third insulating member 43 electrically insulates the first control electrode 53 and the second electrode 52 from each other.

As shown in FIG. 2, the first semiconductor region 11 may include a sixth semiconductor region 16 of the first conductivity type as a partial region. At least a part of the sixth semiconductor region 16 is between the second control electrode 54 and the other part of the first semiconductor region 11. At least a part of the second insulating member 42 is between the second control electrode 54 and the sixth semiconductor region 16. The second insulating member 42 may be in contact with the sixth semiconductor region 16.

For example, a sixth impurity concentration of the first conductivity type in the sixth semiconductor region 16 may be equal to or higher than a first impurity concentration of the first conductivity type in the other part of the first semiconductor region 11. The sixth impurity concentration may be higher than the first impurity concentration.

As shown in FIG. 2, at least a part of the fourth semiconductor region 14 may be provided between the fifth semiconductor region 15 and the sixth semiconductor region 16. At least a part of the fourth semiconductor region 14 may be in contact with the second insulating member 42. A part of the sixth semiconductor region 16 may be provided between the fourth semiconductor region 14 and the first semiconductor region 11.

As shown in FIG. 2, the first semiconductor region 11 may include a seventh semiconductor region 17 of the first conductivity type as a partial region. The seventh semiconductor region 17 is, for example, between the fourth semiconductor region 14 and another part of the first semiconductor region 11. The seventh semiconductor region 17 is in contact with the sixth semiconductor region 16. A seventh impurity concentration of the first conductivity type in the seventh semiconductor region 17 may be higher than the first impurity concentration of the first conductivity type in the other part of the first semiconductor region 11.

In this example, a direction from the second control electrode 54 to the fourth semiconductor region 14 is along a first direction D1. A direction from the second control electrode 54 to the fifth semiconductor region 15 is along the first direction D1. A direction from the second control electrode 54 to the sixth semiconductor region 16 is along the first direction D1. A direction from the fourth semiconductor region 14 to the fifth semiconductor region 15 is along a second direction D2. The second direction D2 crosses the first direction D1. At least a part of the second control electrode 54 may extend along a third direction D3. The third direction D3 crosses a plane including the first direction D1 and the second direction D2. A structure including the second control electrode 54 corresponds to, for example, a planar type transistor.

In this example, a direction from the first control electrode 53 to the second semiconductor region 12 is along a fourth direction D4. The fourth direction D4 crosses the first direction D1. A direction from the first control electrode 53 to the third semiconductor region 13 is along the fourth direction D4. At least a part of the first control electrode 53 may extend along a fifth direction D5. The fifth direction D5 crosses a plane including the first direction D1 and the fourth direction D4.

A part 11p of the first semiconductor region 11 is between the first electrode 51 and the first control electrode 53. A direction from the first control electrode 53 to another part 11q of the first semiconductor region 11 crosses the first direction D1. This direction is, for example, the fourth direction D4. The structure including the first control electrode 53 corresponds to, for example, a trench-type transistor.

The first direction D1 is defined as a Z-axis direction. A direction perpendicular to the Z-axis direction is defined as an X-axis direction. A direction perpendicular to the Z-axis direction and the X-axis direction is defined as a Y-axis direction. The second direction D2 may be, for example, the X-axis direction. The third direction D3 may be, for example, the Y-axis direction.

The fourth direction D4 may be along the second direction D2 or may cross the second direction D2. The fifth direction D5 may be along the second direction D2 or may cross the second direction D2.

As shown in FIG. 1, the semiconductor member 10M may further include an eighth semiconductor region 18 of the second conductivity type. The eighth semiconductor region 18 is provided between the first semiconductor region 11 and the third insulating member 43. For example, carriers accumulate at a high density. For example, conduction losses are reduced.

Below, several examples of semiconductor devices to which the control circuit 150 according to the embodiment is applied will be described.

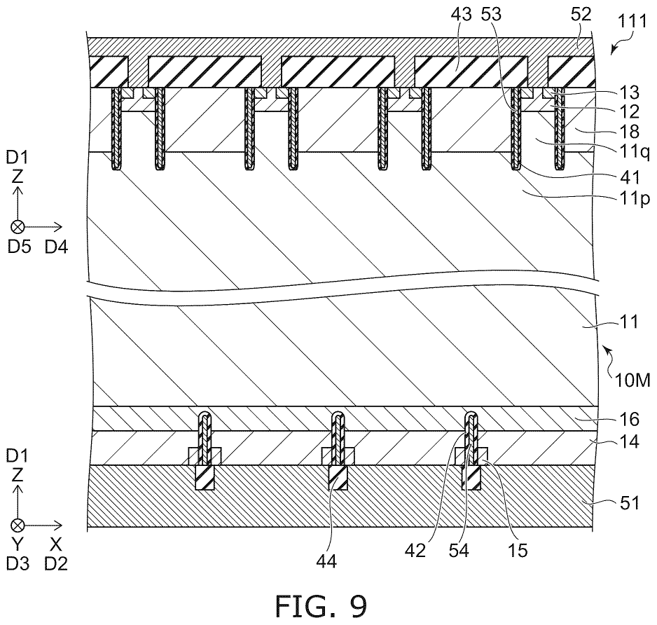

FIGS. 9 to 15 are schematic cross-sectional views illustrating semiconductor devices to which the control circuit according to the first embodiment is applied.

As shown in FIG. 9, in a semiconductor device 111, the direction from the second control electrode 54 to the fourth semiconductor region 14 and the direction from the second control electrode 54 to the fifth semiconductor region 15 cross the first direction D1. In the semiconductor device 111, the structure including the second control electrode 54 corresponds to, for example, a trench type transistor. In the semiconductor device 111, the structure including the first control electrode 53 corresponds to, for example, a trench type transistor.

As shown in FIG. 9, the semiconductor device 111 may include a fourth insulating member 44. The fourth insulating member 44 is provided between the first electrode 51 and the second control electrode 54. The fourth insulating member 44 electrically insulates the first electrode 51 and the second control electrode 54 from each other.

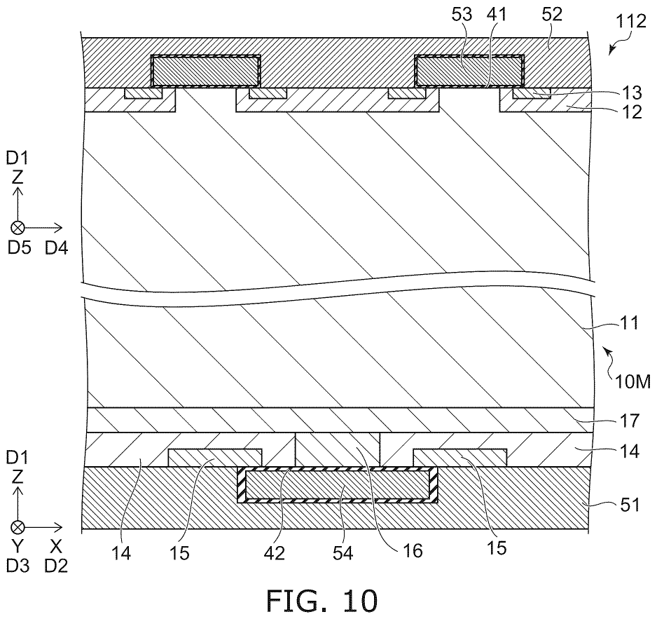

As shown in FIG. 10, in a semiconductor device 112, the direction from the second semiconductor region 12 to the first control electrode 53 and the direction from the third semiconductor region 13 to the first control electrode 53 are along the first direction D1. In the semiconductor device 112, the structure including the first control electrode 53 corresponds to, for example, a planar type transistor. The structure including the second control electrode 54 corresponds to, for example, a planar type transistor.

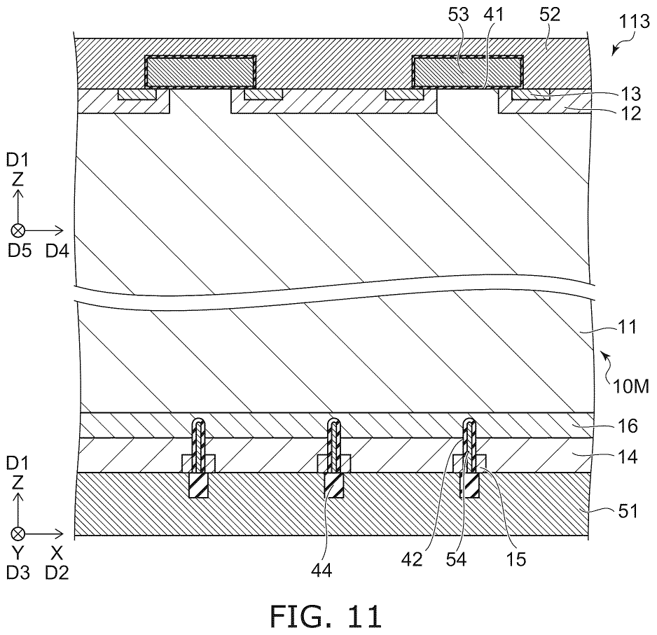

As shown in FIG. 11, in a semiconductor device 113, the structure including the first control electrode 53 corresponds to, for example, a planar transistor. The structure including the second control electrode 54 corresponds to, for example, a trench transistor.

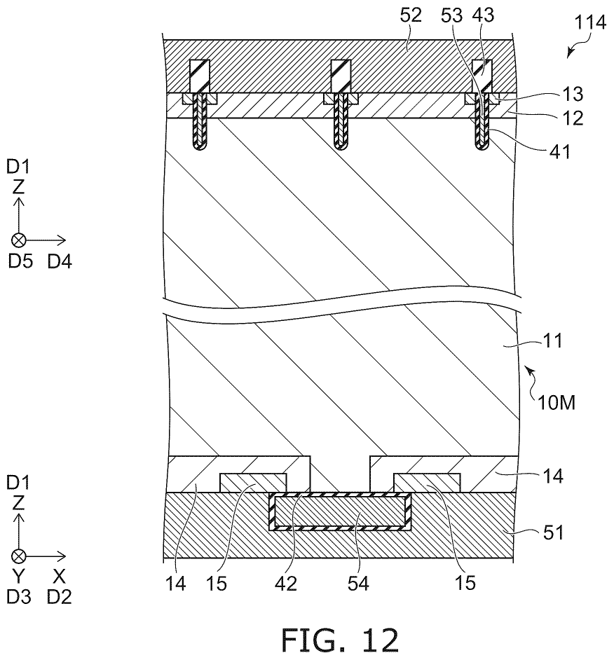

As shown in FIG. 12, in a semiconductor device 114, the structure including the first control electrode 53 corresponds to, for example, a trench transistor. The structure including the second control electrode 54 corresponds to, for example, a planar transistor.

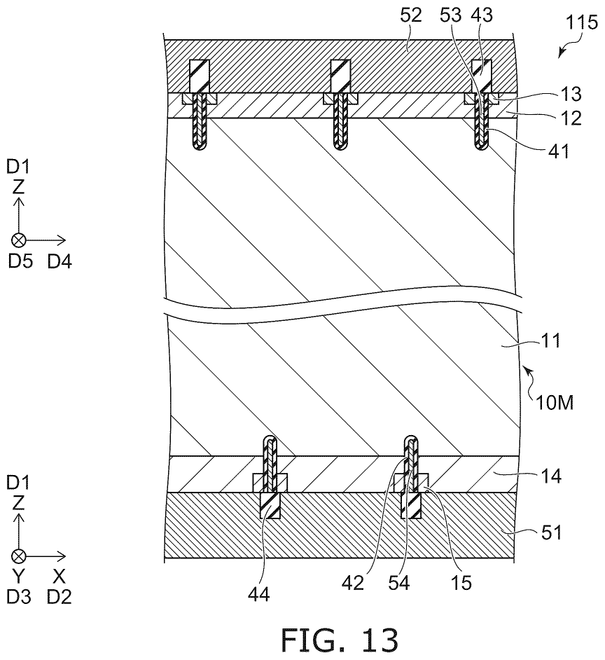

As shown in FIG. 13, in a semiconductor device 115, the structure including the first control electrode 53 corresponds to, for example, a trench type transistor. The structure including the second control electrode 54 corresponds to, for example, a trench type transistor.

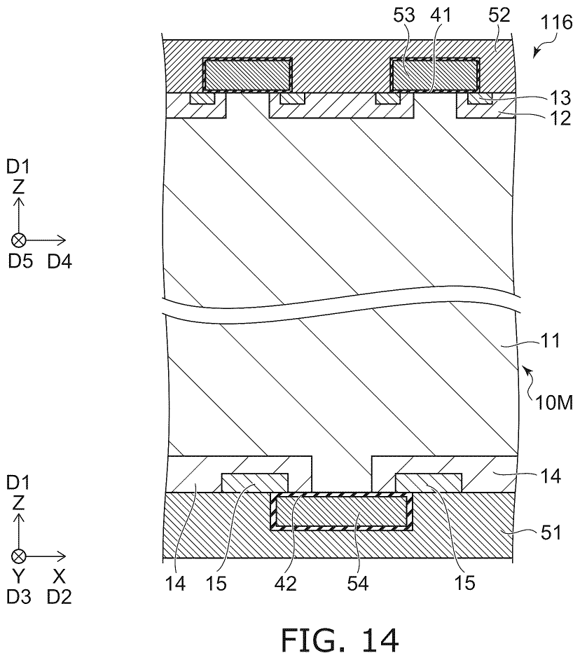

As shown in FIG. 14, in a semiconductor device 116, the structure including the first control electrode 53 corresponds to, for example, a planar type transistor. The structure including the second control electrode 54 corresponds to, for example, a planar type transistor.

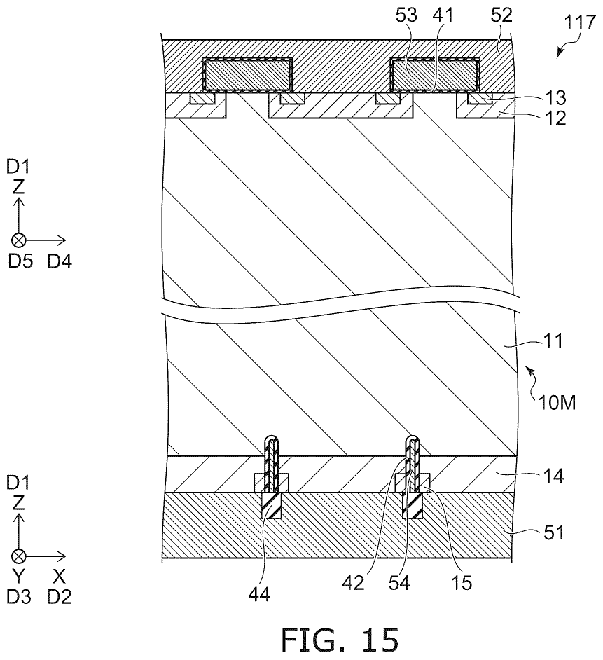

As shown in FIG. 15, in a semiconductor device 117, the structure including the first control electrode 53 corresponds to, for example, a planar type transistor. The structure including the second control electrode 54 corresponds to, for example, a trench type transistor.

### Second Embodiment

The second embodiment relates to a semiconductor system 210 (see FIG. 2). The semiconductor system 210 according to the embodiment includes the semiconductor device 110 and the control circuit 150. In the embodiment, a semiconductor system capable of reducing losses can be provided.

In the embodiment, information on the shape of the semiconductor region is obtained, for example, from an electron microscope image. Information on the composition and element concentration is obtained, for example, from EDX (Energy Dispersive X-ray Spectroscopy) or SIMS (Secondary Ion Mass Spectrometry).

The embodiment may include the following technical proposals:

### Technical Proposal 1

A control circuit for a semiconductor device, comprising:
a controller configured to control a semiconductor device,
the semiconductor device including:
   a first electrode;
   a second electrode;
   a semiconductor member provided between the first electrode and the second electrode;
   a first control electrode; and
   a second control electrode,
at least a part of the semiconductor member being between the first electrode and the first control electrode,
at least a part of the semiconductor member being between the second control electrode and the second electrode,
the controller being configured to perform a second control-on operation multiple times in a first control-on period, to change a second control potential of the second control electrode from a first potential to a second potential,
a first condition or a second condition being satisfied,
in the first condition, in the first control-on period, a first control potential of the first control electrode being equal to or greater than a first threshold voltage,
in the first condition, the first potential being less than a second threshold voltage at the second control electrode and the second potential being equal to or greater than the second threshold voltage,
in the second condition, in the first control-on period, the first control potential of the first control electrode being equal to or less than the first threshold voltage,
in the second condition, the first potential being equal to or greater than the second threshold voltage at the second control electrode and the second potential being less than the second threshold voltage.

### Technical Proposal 2

The control circuit for the semiconductor device according to Technical proposal 1, wherein
the controller is configured to perform the second control-on operation N times,
the “N” is an integer equal to or greater than 2,
after a (N−1)th “second control-on operation” and before a Nth “second control-on operation”, the controller is configured to perform a (N−1)th “second control-off operation” to change the second control potential from the second potential to the first potential, and
a time between a reference time at which the first control potential exceeds the first threshold voltage and a time of the (N−1)th “second control-off operation” is 0.99 times or less a length of the first control-on period.

### Technical Proposal 3

The control circuit for the semiconductor device according to Technical proposal 1, wherein
the controller performs the second control-on operation N times,
the “N” is an integer equal to or greater than 2, and
a time between a reference time at which the first control potential exceeds the first threshold voltage and a start time of the first second control-on operation is equal to or greater than 0.01 times a length of the first control-on period

### Technical Proposal 4

The control circuit for the semiconductor device according to Technical proposal 1, wherein
the controller performs the second control-on operation N times,
“N” is an integer equal to or greater than 2, after an nth “second control-on operation” and before a (n+1)th “second control-on operation”, the controller is configured to perform an nth “second control-off operation” to change the second control potential from the second potential to the first potential,
the “n” is an integer not less than 1 and not more than (N−1), and
a time between the nth “second control-on operation” and the nth “second control-off operation” is 2 μs or less.

### Technical Proposal 5

The control circuit for the semiconductor device according to Technical proposal 1, wherein
the controller performs the second control-on operation N times,
the “N” is an integer equal to or greater than 2, after an nth “second control-on operation” and before a (n+1)th second control-on operation, the controller is configured to perform an nth “second control-off operation” to change the second control potential from the second potential to the first potential,
the “n” is an integer not less than 1 and not more than (N−2),
an ON time between a time of the nth “second control-on operation” and a time of the nth “second control-off operation” is shorter than an OFF time between a time of the nth “second control-off operation” and the (n+1)th “second control-on operation”.

### Technical Proposal 6

The control circuit for the semiconductor device according to Technical proposal 1, wherein
the controller performs the second control-on operation N times,
the “N” is an integer equal to or greater than 2,
after a (n−1)th “second control-on operation” and before an nth “second control-on operation”, the controller is configured to perform a (n−1)th “second control-off operation” to change the second control potential from the second potential to the first potential,
the “n” is an integer not less than 1 and not more than (N−1), first to (n−1)th “second control-on operations” include applying a pulse to the second control electrode, and
a period of the pulse is 5 μs or less in the first to (N−1)th “second control-on operations”.

### Technical Proposal 7

The control circuit for the semiconductor device according to Technical proposal 6, wherein
a period of the pulse is constant in the first to the (n−1)th “second control-on operations”, and
the pulse is applied continuously.

### Technical Proposal 8

The control circuit for the semiconductor device according to Technical proposal 1, wherein
the controller performs the second control-on operation N times,
the “N” is an integer equal to or greater than 2,
after a (n−1)th “second control-on operation” and before an nth “second control-on operation”, the controller is configured to perform a (n−1)th “second control-off operation” to change the second control potential from the second potential to the first potential,
the “n” is an integer not less than 1 and not more than (N−1),
first to (n−1)th “second control-on operations” include applying a pulse to the second control electrode, and
in the first to (n−1)th “second control-on operations”, a duty ratio of the pulse is 0.5 or less.

### Technical Proposal 9

The control circuit for the semiconductor device according to Technical proposal 1, wherein
the controller performs the second control-on operation N times,
the “N” is an integer equal to or greater than 2,
after an nth second control-on operation and before a (n+1)th second control-on operation”, the controller is configured to perform an nth “second control-off operation” to change the second control potential from the second potential to the first potential,
the “n is an integer not less than 1 and not more than (N−1),
after an Nth “second control-on operation”, the controller is configured to perform an Nth “second control-off operation” to change the second control potential from the second potential to the first potential, and
a time between a time of the Nth “second control-on operation” and a time of the Nth “second control-off operation” is longer than a time between a time of the nth “second control-on operation” and a time of the nth “second control-off operation”.

### Technical Proposal 10

The control circuit for the semiconductor device according to any one of Technical proposals 1 to 9, wherein
the second potential in one of the plurality of performing the second control-on operation is different from the second potential in another one of the plurality of performing the second control-on operation.

### Technical Proposal 11

The control circuit for the semiconductor device according to any one of Technical proposals 1 to 9, wherein
the first potential in one of the plurality of performing the second control-on operation is different from the first potential in another one of the plurality of performing the second control-on operation.

### Technical Proposal 12

The control circuit for the semiconductor device according to Technical proposal 1, wherein
the controller performs the second control-on operation N times,
the “N” is an integer equal to or greater than 2,
in first to (N−1)th “second control-on operations”, the second control potential is controlled by a two-value pulse,
the controller is configured to perform an Nth “second control-off operation” after the Nth second control-on operation,
in the Nth “second control-off operation”, the second control potential changes from the second potential to the first potential, and
in at least one of the Nth “second control-on operation” and the Nth “second control-off operation”, the second control potential is controlled by a pulse having three or more values.

### Technical Proposal 13

The control circuit for the semiconductor device according to Technical proposal 12, wherein
a potential of the pulse having three or more values changes from the second potential to a third potential after changing from the first potential to the second potential, and becomes the first potential after changing to the third potential,
the third potential is between the first potential and the second potential,
before an end of the first control-on period, the second control potential is the second potential, and
after the end of the first control-on period, the second control potential becomes the third potential.

### Technical Proposal 14

The control circuit for the semiconductor device according to any one of Technical proposals 1 to 12, wherein
the controller is configured to change the second control potential to the first potential after the first control-on period.

### Technical Proposal 15

The control circuit for the semiconductor device according to any one of Technical proposal 1 to 14, wherein
the semiconductor device further includes
a first insulating member, and
a second insulating member,
the semiconductor member includes
   a first semiconductor region of a first conductivity type,
   a second semiconductor region of a second conductivity type provided between the first semiconductor region and the second electrode,
   a third semiconductor region of the first conductivity type provided between at least a part of the second semiconductor region and the second electrode,
   a fourth semiconductor region of the second conductivity type, the fourth semiconductor region being electrically connected to the first electrode and provided between the first electrode and the first semiconductor region, and
   a fifth semiconductor region of the first conductivity type, the fifth semiconductor region being electrically connected to the first electrode,
at least a part of the first insulating member is provided between the first control electrode and the second semiconductor region,
the fifth semiconductor region is provided between the first electrode and at least a part of the fourth semiconductor region, and
at least a part of the second insulating member is provided between the second control electrode and the first semiconductor region and between the second control electrode and the fourth semiconductor region.

### Technical Proposal 16

The control circuit for the semiconductor device according to Technical proposal 15, wherein
the semiconductor member further includes a sixth semiconductor region of the first conductivity type,
at least a part of the sixth semiconductor region is between the second control electrode and the first semiconductor region, and
the at least the part of the second insulating member is between the second control electrode and the sixth semiconductor region.

### Technical Proposal 17

The control circuit for the semiconductor device according to Technical proposal 16, wherein
at least a part of the fourth semiconductor region is between the fifth semiconductor region and the sixth semiconductor region.

### Technical Proposal 18

The control circuit for the semiconductor device according to Technical proposal 17, wherein
a sixth impurity concentration of the first conductivity type in the sixth semiconductor region is equal to or greater than a first impurity concentration of the first conductivity type in the first semiconductor region.

### Technical Proposal 19

The control circuit for the semiconductor device according to Technical proposal 18, wherein
a part of the sixth semiconductor region is between the fourth semiconductor region and the first semiconductor region.

### Technical Proposal 20

A semiconductor system comprising:
the control circuit according to any one of Technical proposals 1 to 19; and
the semiconductor device.

### Technical Proposal 21

A control circuit for a semiconductor device, comprising:
a controller configured to control a semiconductor device,
the semiconductor device including:
   a first electrode;
   a second electrode;
   a semiconductor member provided between the first electrode and the second electrode;
   a first control electrode; and
   a second control electrode,
at least a part of the semiconductor member being between the first electrode and the first control electrode,
at least a part of the semiconductor member being between the second control electrode and the second electrode,
the controller being configured to perform an operation to chang a second control potential of the second control electrode from a first potential to a second potential and from the second potential to the first potential multiple times in a first control-on period, a first control potential of the first control electrode being equal to or lower than a first threshold voltage in first control-on period,
one of the first potential and the second potential being higher than a second threshold voltage of the second control electrode, and
another one of the first potential and the second potential being lower than the second threshold voltage of the second control electrode.

### Technical Proposal 22

The control circuit for the semiconductor device according to any one of technical proposals 1 to 14, wherein
the semiconductor device is an IGBT.

According to the embodiment, a control circuit for a semiconductor device and a semiconductor system capable of reducing losses are provided.

In this specification, “perpendicular” and “parallel” do not only mean strictly perpendicular and strictly parallel, but also include, for example, variations in the manufacturing process, and may mean substantially perpendicular and substantially parallel.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in semiconductor devices such as electrodes, semiconductor members, semiconductor regions, insulating members, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all control circuits for semiconductor devices and all semiconductor systems practicable by an appropriate design modification by one skilled in the art based on the control circuits for semiconductor devices and the semiconductor systems described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A control circuit for a semiconductor device, comprising:
a controller configured to control a semiconductor device,
the semiconductor device including:
a first electrode;
a second electrode;
a semiconductor member provided between the first electrode and the second electrode;
a first control electrode; and
a second control electrode,
at least a part of the semiconductor member being between the first electrode and the first control electrode,
at least a part of the semiconductor member being between the second control electrode and the second electrode,
the controller being configured to perform a second control-on operation multiple times in a first control-on period, to change a second control potential of the second control electrode from a first potential to a second potential,
a first condition or a second condition being satisfied,
in the first condition, in the first control-on period, a first control potential of the first control electrode being equal to or greater than a first threshold voltage,
in the first condition, the first potential being less than a second threshold voltage at the second control electrode and the second potential being equal to or greater than the second threshold voltage,
in the second condition, in the first control-on period, the first control potential of the first control electrode being equal to or less than the first threshold voltage,
in the second condition, the first potential being equal to or greater than the second threshold voltage at the second control electrode and the second potential being less than the second threshold voltage.

2. The control circuit according to claim 1, wherein
the controller is configured to perform the second control-on operation N times,
the “N” is an integer equal to or greater than 2,
after a (N−1)th “second control-on operation” and before a Nth “second control-on operation”, the controller is configured to perform a (N−1)th “second control-off operation” to change the second control potential from the second potential to the first potential, and
a time between a reference time at which the first control potential exceeds the first threshold voltage and a time of the (N−1)th “second control-off operation” is 0.99 times or less a length of the first control-on period.

3. The control circuit according to claim 1, wherein
the controller performs the second control-on operation N times,
the “N” is an integer equal to or greater than 2, and
a time between a reference time at which the first control potential exceeds the first threshold voltage and a start time of the first second control-on operation is equal to or greater than 0.01 times a length of the first control-on period.

4. The control circuit according to claim 1, wherein
the controller performs the second control-on operation N times,
“N” is an integer equal to or greater than 2,
after an nth “second control-on operation” and before a (n+1)th “second control-on operation”, the controller is configured to perform an nth “second control-off operation” to change the second control potential from the second potential to the first potential,
the “n” is an integer not less than 1 and not more than (N−1), and
a time between the nth “second control-on operation” and the nth “second control-off operation” is 2 μs or less.

5. The control circuit according to claim 1, wherein
the controller performs the second control-on operation N times,
the “N” is an integer equal to or greater than 2,
after an nth “second control-on operation” and before a (n+1)th second control-on operation, the controller is configured to perform an nth “second control-off operation” to change the second control potential from the second potential to the first potential,
the “n” is an integer not less than 1 and not more than (N−2),
an ON time between a time of the nth “second control-on operation” and a time of the nth “second control-off operation” is shorter than an OFF time between a time of the nth “second control-off operation” and the (n+1)th “second control-on operation”.

6. The control circuit according to claim 1, wherein
the controller performs the second control-on operation N times,
the “N” is an integer equal to or greater than 2,
after a (n−1)th “second control-on operation” and before an nth “second control-on operation”, the controller is configured to perform a (n−1)th “second control-off operation” to change the second control potential from the second potential to the first potential,
the “n” is an integer not less than 1 and not more than (N−1),
first to (n−1)th “second control-on operations” include applying a pulse to the second control electrode, and
a period of the pulse is 5 μs or less in the first to (N−1)th “second control-on operations”.

7. The control circuit according to claim 6, wherein
a period of the pulse is constant in the first to the (n−1)th “second control-on operations”, and
the pulse is applied continuously.

8. The control circuit according to claim 1, wherein
the controller performs the second control-on operation N times,
the “N” is an integer equal to or greater than 2,
after a (n−1)th “second control-on operation” and before an nth “second control-on operation”, the controller is configured to perform a (n−1)th “second control-off operation” to change the second control potential from the second potential to the first potential,
the “n” is an integer not less than 1 and not more than (N−1),
first to (n−1)th “second control-on operations” include applying a pulse to the second control electrode, and
in the first to (n−1)th “second control-on operations”, a duty ratio of the pulse is 0.5 or less.

9. The control circuit according to claim 1, wherein
the controller performs the second control-on operation N times,
the “N” is an integer equal to or greater than 2,
after an nth second control-on operation and before a (n+1)th second control-on operation”, the controller is configured to perform an nth “second control-off operation” to change the second control potential from the second potential to the first potential,
the “n is an integer not less than 1 and not more than (N−1),
after an Nth “second control-on operation”, the controller is configured to perform an Nth “second control-off operation” to change the second control potential from the second potential to the first potential, and
a time between a time of the Nth “second control-on operation” and a time of the Nth “second control-off operation” is longer than a time between a time of the nth “second control-on operation” and a time of the nth “second control-off operation”.

10. The control circuit according to claim 1, wherein
the second potential in one of the plurality of performing the second control-on operation is different from the second potential in another one of the plurality of performing the second control-on operation.

11. The control circuit according to claim 1, wherein
the first potential in one of the plurality of performing the second control-on operation is different from the first potential in another one of the plurality of performing the second control-on operation.

12. The control circuit according to claim 1, wherein
the controller performs the second control-on operation N times,
the “N” is an integer equal to or greater than 2,
in first to (N−1)th “second control-on operations”, the second control potential is controlled by a two-value pulse,
the controller is configured to perform an Nth “second control-off operation” after the Nth second control-on operation,
in the Nth “second control-off operation”, the second control potential changes from the second potential to the first potential, and
in at least one of the Nth “second control-on operation” and the Nth “second control-off operation”, the second control potential is controlled by a pulse having three or more values.

13. The control circuit according to claim 12, wherein
a potential of the pulse having three or more values changes from the second potential to a third potential after changing from the first potential to the second potential, and becomes the first potential after changing to the third potential,
the third potential is between the first potential and the second potential,
before an end of the first control-on period, the second control potential is the second potential, and
after the end of the first control-on period, the second control potential becomes the third potential.

14. The control circuit according to claim 1, wherein
the controller is configured to change the second control potential to the first potential after the first control-on period.

15. The control circuit according to claim 1, wherein
the semiconductor device further includes
a first insulating member, and
a second insulating member,
the semiconductor member includes
a first semiconductor region of a first conductivity type,
a second semiconductor region of a second conductivity type provided between the first semiconductor region and the second electrode,
a third semiconductor region of the first conductivity type provided between at least a part of the second semiconductor region and the second electrode,
a fourth semiconductor region of the second conductivity type, the fourth semiconductor region being electrically connected to the first electrode and provided between the first electrode and the first semiconductor region, and
a fifth semiconductor region of the first conductivity type, the fifth semiconductor region being electrically connected to the first electrode,
at least a part of the first insulating member is provided between the first control electrode and the second semiconductor region,
the fifth semiconductor region is provided between the first electrode and at least a part of the fourth semiconductor region, and
at least a part of the second insulating member is provided between the second control electrode and the first semiconductor region and between the second control electrode and the fourth semiconductor region.

16. The control circuit according to claim 15, wherein
the semiconductor member further includes a sixth semiconductor region of the first conductivity type,
at least a part of the sixth semiconductor region is between the second control electrode and the first semiconductor region, and
the at least the part of the second insulating member is between the second control electrode and the sixth semiconductor region.

17. The control circuit according to claim 16, wherein
at least a part of the fourth semiconductor region is between the fifth semiconductor region and the sixth semiconductor region.

18. The control circuit according to claim 17, wherein
a sixth impurity concentration of the first conductivity type in the sixth semiconductor region is equal to or greater than a first impurity concentration of the first conductivity type in the first semiconductor region.

19. A semiconductor system comprising:
the control circuit according to claim 1; and
the semiconductor device.

20. A control circuit for a semiconductor device, comprising:
a controller configured to control a semiconductor device,
the semiconductor device including:
a first electrode;
a second electrode;
a semiconductor member provided between the first electrode and the second electrode;
a first control electrode; and
a second control electrode,
at least a part of the semiconductor member being between the first electrode and the first control electrode,
at least a part of the semiconductor member being between the second control electrode and the second electrode,
the controller being configured to perform an operation to chang a second control potential of the second control electrode from a first potential to a second potential and from the second potential to the first potential multiple times in a first control-on period, a first control potential of the first control electrode being equal to or lower than a first threshold voltage in first control-on period,
one of the first potential and the second potential being higher than a second threshold voltage of the second control electrode, and
another one of the first potential and the second potential being lower than the second threshold voltage of the second control electrode.
